(19) United States
(12) Patent Application Publication
(10) Pub. No.: US 2012/0104411 A1
(43) Pub. Date: May 3, 2012

(54) TEXTURED III-V SEMICONDUCTOR

(75) Inventors: Michael Iza, Santa Barbara, CA (US); Carl J. Neufeld, Goleta, CA (US); Samantha C. Cruz, Goleta, CA (US); Robert M. Farrell, Goleta, CA (US); James S. Speck, Goleta, CA (US); Shuji Nakamura, Santa Barbara, CA (US); Steven P. DenBaars, Goleta, CA (US); Umesh K. Mishra, Montecito, CA (US)

(73) Assignee: THE REGENTS OF THE UNIVERSITY OF CALIFORNIA, Oakland, CA (US)

(21) Appl. No.: 13/283,211

(22) Filed: Oct. 27, 2011

Related U.S. Application Data
(60) Provisional application No. 61/408,297, filed on Oct. 29, 2010.

(51) Int. Cl. H01L 31/0236; H01L 31/18; H01L 31/0352; H01L 31/0304; H01L 33/32; H01L 33/58; H01L 33/22

(52) U.S. Cl. 257/76; 438/29; 438/71; 257/98; 257/432; 257/95; 257/184; 257/E31.13; 257/E33.074; 257/E31.019; 257/E33.023

(57) ABSTRACT

A method for fabricating a III-nitride semiconductor film, comprising depositing or growing a III-nitride semiconductor film in a semiconductor light absorbing or light emitting device structure; and growing a textured or structured surface of the III-nitride nitride semiconductor film in situ with the growing or the deposition of the III-nitride semiconductor film, by controlling the growing of the III-nitride semiconductor film to obtain a texture of the textured surface, or one or more structures of the structured surface, that increase output power of light from the light emitting device, or increase absorption of light in the light absorbing device.

### CROSS REFERENCE TO RELATED APPLICATIONS

This application claims the benefit under 35 U.S.C. Section 119(e) of co-pending and commonly-assigned U.S. Provisional Application Ser. No. 61/408,297 filed on Oct. 29, 2010, by Michael Iza, James S. Speck, Shuji Nakamura, Steven P. DenBaars, Carl J. Neufeld, Samantha C. Cruz, Robert M. Farrell and Umesh K. Mishra, entitled “TEXTURED III-V SEMICONDUCTOR,” attorney's docket number 30794.401-US-P1 (2011-232-1), which application is incorporated by reference herein.

This application is related to the following co-pending and commonly-assigned U.S. patent applications:

U.S. Utility application Ser. No. 12/576,122, filed on Oct. 8, 2009, by Tetsuo Fujii, Yan Gao, Evelyn L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-US-C1 (2004-063), which application is a continuation U.S. Utility application Ser. No. 10/581,940, filed on Jun. 7, 2006, now U.S. Pat. No. 7,704,763, by Tetsuo Fujii, Yan Gao, Evelyn L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-US-WO (2004-063), which application claims the benefit under 35 U.S.C. Section 365(c) of PCT Application Serial No. US2003/039211, filed on Dec. 9, 2003, by Tetsuo Fujii, Yan Gao, Evelyn L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-WO-01 (2004-063);

U.S. Utility application Ser. No. 12/464,711, filed on May 12, 2009, by Adele Tamboli, Evelyn L. Hu, Steven P. DenBaars and Shuji Nakamura, entitled “PHOTOELECTROCHEMICAL ROUGHENING OF P-SIDE-UP GaN-BASED LIGHT EMITTING DIODES,” attorney's docket number 30794.271-US-U1 (2008-535), which application claims the benefit under 35 U.S.C. Section 119(e) of U.S. Provisional Application Ser. No. 61/052,417, filed on May 12, 2008, by Adele Tamboli, Evelyn L. Hu, Steven P. DenBaars, and Shuji Nakamura, entitled “PHOTOELECTROCHEMICAL ROUGHENING OF Ga-FACE, P-SIDE-UP GaN BASED LIGHT EMITTING DIODES,” attorney's docket number 30794.271-US-P1 (2008-535);

U.S. Utility application Ser. No. 12/464,723, filed on May 12, 2009, by Adele Tamboli, Evelyn L. Hu, Matthew C. Schmidt, Shuji Nakamura, and Steven P. DenBaars, entitled “PHOTOELECTROCHEMICAL ETCHING OF P-TYPE SEMICONDUCTOR HETEROSTRUCTURES,” attorney's docket number 30794.272-US-U1 (2008-533), which application claims the benefit under 35 U.S.C. Section 119(e) of U.S. Provisional Application Ser. No. 61/052,421, filed on May 12, 2008, by Adele Tamboli, Evelyn L. Hu, Matthew C. Schmidt, Shuji Nakamura, and Steven P. DenBaars entitled “PHOTOELECTROCHEMICAL ETCHING OF P-TYPE SEMICONDUCTOR HETEROSTRUCTURES,” attorney's docket number 30794.272-US-P1 (2008-533);

U.S. Utility patent application Ser. No. 12/576,846, filed on Oct. 9, 2009, by Adele Tamboli, Evelyn L. Hu, and James S. Speck, entitled “PHOTOELECTROCHEMICAL ETCHING FOR CHIP SHAPING OF LIGHT EMITTING DIODES,” attorney's docket number 30794.289-US-U1 (2009-157), which application claims the benefit under 35 U.S.C. Section 119(e) of U.S. Provisional Application Ser. No. 61/104,015, filed on Oct. 9, 2008, by Adele Tamboli, Evelyn L. Hu, and James S. Speck, entitled “PHOTOELECTROCHEMICAL ETCHING FOR CHIP SHAPING OF LIGHT EMITTING DIODES,” attorney's docket number 30794.289-US-P1 (2009-157); and

U.S. Utility application Ser. No. 12/697,857, filed on Feb. 1, 2010, by Adele Tamboli, Evelyn L. Hu, Arpan Chakraborty, and Steven P. DenBaars, entitled “PHOTOELECTROCHEMICAL ETCHING FOR LASER FACETS,” attorney's docket number 30794.301-US-U1 (2009-360), which application claims the benefit under 35 U.S.C. Section 119(e) of U.S. Provisional Application Ser. No. 61/148,679, filed on Jan. 30, 2009, by Adele Tamboli, Evelyn L. Hu, Arpan Chakraborty, and Steven P. DenBaars, entitled “PHOTOELECTROCHEMICAL ETCHING FOR LASER FACETS,” attorney's docket number 30794.301-US-P1 (2009-360);

all of which applications are incorporated by reference herein.

### BACKGROUND OF THE INVENTION

1. Field of the Invention

The present invention relates generally to the growth of textured films.

2. Description of the Related Art

Current state of the art prior to the present invention required that the material texturing step occur after the deposition step of the semiconductor material on the substrate. Since nitride based devices typically grow in the (0001) direction or Ga-face direction, the substrate must be removed in order to expose the N-face of the semiconductor material. Once the N-face was exposed, Photoelectrochemical (PEC) etching was then employed to provide a textured semiconductor material. PEC of the Ga-Face can also be employed but also requires that the process occur after the material deposition steps.

### SUMMARY OF THE INVENTION

The present invention describes a nitride based device structure with enhanced light extraction and enhanced light absorption by use of a textured nitride film. The present invention includes a method for fabricating nitride devices comprising growing textured nitride semiconductor films in, or on, the devices.

The present invention describes a method for fabricating a III-nitride semiconductor film, comprising depositing or growing a III-nitride semiconductor film in a semiconductor light absorbing or light emitting device structure; and growing a textured or structured surface of the III-nitride nitride semiconductor film in situ with the growing or the deposition of the III-nitride semiconductor film, by controlling the growing of the III-nitride semiconductor film to obtain a texture of the textured surface, or one or more structures of the structured surface, that increase output power of light from the light emitting device, or increase absorption of light in the light absorbing device.

The controlling can be such that the texture or the structures' profile is rough as compared to a wavelength of the light in the group III-nitride semiconductor film.

The controlling can be such that the texture or the structures scatter the light by Rayleigh scattering, Mie scattering, or geometric scattering.

The controlling can be such that the structures have a width at a base of the structures that is larger than a width at a top of the structures.

The controlling can be such that the structures have a height and a base width of 200 nanometers or more, or larger than a wavelength of the light.

The controlling can be such that sidewalls of the structures are inclined at an angle greater than a critical angle for the light's extraction from, or the light's insertion into the film, or such that total internal reflection of the light inside the film or outside the film is suppressed or minimized.

The controlling can be such that a density of the structures is at least 50 structures per 25 microns square.

The controlling can be such that the structures or the texture continuously cover an entire light receiving or light emitting surface of the device.

The controlling can be such that the light incident on the textured or structured surface deviates from its original path and has a pass path length, through a light absorbing region of the light absorbing that is a solar cell, that is longer than a path length of the light incident on a planar surface of a III-nitride semiconductor film used in a solar cell.

The III-nitride semiconductor film can be deposited in a light emitting diode device or in a solar cell device, for example.

The III-nitride semiconductor film is deposited on a surface, on a top, on a bottom, or within, the semiconductor device.

The III-nitride semiconductor film can be deposited and doped with Mg, Fe, C, O, Si, B or H. The III-nitride semiconductor film can comprise one or more layers of intentionally doped or unintentionally doped materials. The III-nitride semiconductor film can comprise multiple layers having varying or graded compositions. The III-nitride semiconductor film can comprise a heterostructure comprising layers of dissimilar (Al, Ga, In, B)N composition. The III-nitride semiconductor film can comprise GaN, AlN, InN, AlGaN, InGaN or AlInN.

The III-nitride semiconductor film can be a film grown in any crystallographic nitride direction, including a conventional c-plane, a nonpolar a-plane or m-plane, or any semipolar plane oriented nitride semiconductor crystal.

The present invention further discloses a light emitting or light absorbing device, comprising a III-nitride semiconductor film grown or deposited in a semiconductor light absorbing or light emitting device structure; and a texture or one or more structures grown onto a surface of the III-nitride nitride semiconductor film to form a textured surface, wherein the texture or the structures of the structured surface increase an output power of light from the light emitting device, or increase absorption of light in the light absorbing device.

### BRIEF DESCRIPTION OF THE DRAWINGS

Referring now to the drawings in which like reference numbers represent corresponding parts throughout:

FIG. 1 is a flowchart illustrating a method of fabricating a III-nitride semiconductor film.

FIG. 2 is a Scanning Electron Micrograph of a textured nitride semiconductor film grown according to an embodiment of the present invention.

FIG. 3 is a schematic cross-sectional view of III-nitride solar cells showing path length difference for (a) a solar cell with a flat surface and (b) a solar cell with a roughened surface grown according to the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention describes a textured nitride semiconductor film, comprising a grown textured surface.

A purpose of this invention is to improve the performance of light emitting and light absorbing semiconductor devices such as, light emitting diodes (LEDs) and solar cells. By use of the present invention to texture the semiconductor material, the light extraction efficiency of LEDs can be increased and the light absorption efficiency of solar cells can be enhanced.

Nomenclature

GaN and its ternary and quaternary compounds incorporating aluminum and indium (AlGaN, InGaN, AlInGaN) are commonly referred to using the terms (Al, Ga, In)N, III-nitride, Group III-nitride, nitride, Al_{(1-x-y)}In_{y}GaₓN where 0≦x≦1 and 0≦y≦1, or AlInGaN, as used herein. All these terms are intended to be equivalent and broadly construed to include respective nitrides of the single species, Al, Ga, and In, as well as binary, ternary and quaternary compositions of such Group III metal species. Accordingly, these terms comprehend the compounds AlN, GaN, and InN, as well as the ternary compounds AlGaN, GaInN, and AlInN, and the quaternary compound AlGaInN, as species included in such nomenclature. When two or more of the (Ga, Al, In) component species are present, all possible compositions, including stoichiometric proportions as well as “off-stoichiometric” proportions (with respect to the relative mole fractions present of each of the (Ga, Al, In) component species that are present in the composition), can be employed within the broad scope of the invention. Accordingly, it will be appreciated that the discussion of the invention hereinafter in primary reference to GaN materials is applicable to the formation of various other (Al, Ga, In)N material species. Further, (Al, Ga, In)N materials within the scope of the invention may further include minor quantities of dopants and/or other impurity or inclusional materials. Boron (B) may also be included.

One approach to eliminating the spontaneous and piezoelectric polarization effects in GaN or III-nitride based optoelectronic devices is to grow the III-nitride devices on nonpolar planes of the crystal. Such planes contain equal numbers of Ga (or group III atoms) and N atoms and are charge-neutral. Furthermore, subsequent nonpolar layers are equivalent to one another so the bulk crystal will not be polarized along the growth direction. Two such families of symmetry-equivalent nonpolar planes in GaN are the {11-20} family, known collectively as a-planes, and the {1-100} family, known collectively as m-planes. Thus, nonpolar III-nitride is grown along a direction perpendicular to the (0001) c-axis of the III-nitride crystal.

Another approach to reducing polarization effects in (Ga, Al, In, B)N devices is to grow the devices on semi-polar planes of the crystal. The term “semi-polar plane” (also referred to as “semipolar plane”) can be used to refer to any plane that cannot be classified as c-plane, a-plane, or m-plane. In crystallographic terms, a semi-polar plane may include any plane that has at least two nonzero h, i, or k Miller indices and a nonzero 1 Miller index.

Some commonly observed examples of semi-polar planes include the (11-22), (10-11), and (10-13) planes. Other examples of semi-polar planes in the wurtzite crystal structure include, but are not limited to, (10-12), (20-21), and (10-14). The nitride crystal's polarization vector lies neither within such planes or normal to such planes, but rather lies at some angle inclined relative to the plane's surface normal. For example, the (10-11) and (10-13) planes are at 62.98° and 32.06° to the c-plane, respectively.

The Gallium or Ga face of GaN is the c⁺ or (0001) plane, and the Nitrogen or N-face of GaN or a III-nitride layer is the c⁻ or (0001) plane.

Technical Description

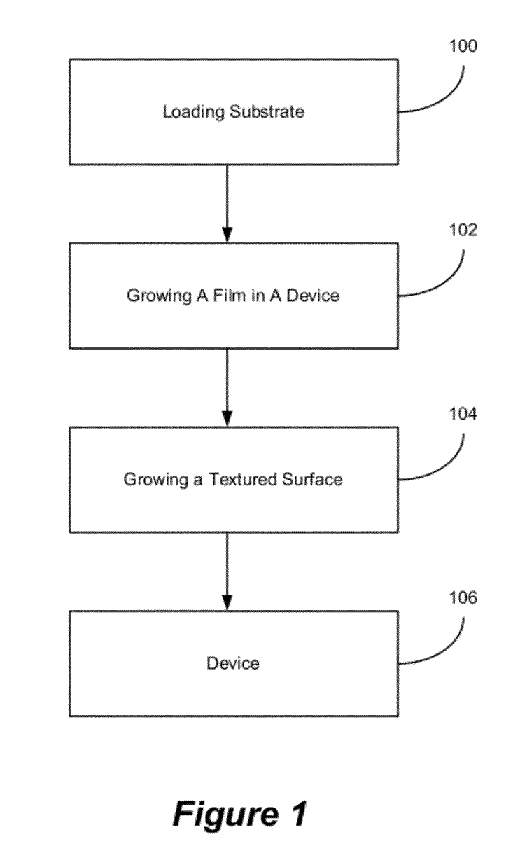

The present invention can be implemented as illustrated in FIG. 1 and described below.

Block 100 represents loading a substrate into a Metal Organic Chemical Vapor Deposition (MOCVD) reactor.

Block 102 represents depositing or growing a nitride semiconductor film in an optoelectronic or electronic device, such as a semiconductor light absorbing or light emitting device structure. The depositing or growing can comprise:

(1) Turning on a heater for the reactor and ramping the temperature in the reactor to a set point temperature, wherein nitrogen and/or hydrogen and/or ammonia flow over the substrate at atmospheric pressure.

(2) After a period of time, decreasing the set point temperature and introducing trimethylgallium (TMGa) and ammonia into the reactor to initiate growth of the GaN nucleation or buffer layer.

(3) After the GaN nucleation layer reaches a desired thickness, shutting off the flow of TMGa and increasing the reactor temperature to a set point.

(4) After the reactor set point temperature is achieved, turning on the flow of TMGa and DiSilane (Si₂H₆) for the growth of n-type GaN doped with silicon.

(5) Once a desired thickness is achieved for the n-type GaN, the temperature set point is decreased for the deposition of an InGaN multi-quantum well (MQW).

(6) After the set point temperature is achieved, turning on a flow of trimethylindium (TMIn) and TMGa for the deposition of the InGaN MQW.

(7) Once a desired thickness is achieved for the MQW, the TMIn flow is shut off and the flow of trimethylaluminium (TMAl) is opened for the deposition of an AlGaN film (electron blocking layer).

(8) After the AlGaN electron blocking layer reaches a desired thickness, shutting off the flow of TMAl, and introducing Bis(cyclopentadienyl)magnesium (Cp2Mg) for the deposition of textured Mg doped GaN.

(9) After the textured Mg doped GaN reaches a desired thickness, shutting off the flow of TMGa and Cp2Mg, and cooling the reactor down while flowing ammonia to preserve the nitride semiconductor thin films.

Block 104 represents growing a textured or structured surface of the III-nitride nitride semiconductor film in situ with the growth or the deposition of the device structure. The textured or structured surface can be grown during, or combination with, the growing step 102. The present invention can vary one or more parameters, e.g., process parameters (including growth parameters), and/or vary layer growth thicknesses in the above steps of Block 102 to achieve a textured surface of a particular layer in Block 102 (e.g., textured surface of Mg doped GaN).

For the deposition of a textured surface, deposition parameters were chosen in order to enhance the textured surface features of the as grown film. This was achieved by the use of higher growth rates and lower temperatures than is typically used. This change in deposition parameters moves the deposition process into a kinetically limited growth regime which results transition from a two-dimensional growth mode to a three-dimensional growth mode, thus achieving a textured surface.

By changing the growth rate and deposition temperature, various degrees of surface texturing can occur in the as grown film. For example, the present invention found that a desired textured surface was obtained by increasing the growth rate by/from 2 angstrom per second to 5 angstrom per second, and decreasing the deposition temperature by approximately 100° C.

Typical temperatures for Metal Organic Chemical Vapor Deposition (MOCVD), to achieve planar growth, are greater than 1000° C. The results obtained in the present invention used temperatures of 900° C. or less. Although these temperatures are accurate they are measured indirectly and thus are not indicative of actual substrate surface temperatures. Accordingly, the present invention also describes a relative temperature change (e.g., decreasing the deposition temperature by 100° C.) instead of an absolute temperature, in order to obtain the desired textured surface.

The growth conditions described above are provided as an example. The present invention is not limited to these growth conditions, and other growth conditions that obtain the desired textured surface can also be used.

The growing can include controlling the growing to obtain a texture of the textured surface, or one or more structures or features of the structured surface, that increase output power of electromagnetic (EM) radiation from an EM radiation emitting device, or increase absorption of EM radiation in an EM radiation absorbing device. The EM radiation can comprise light, e.g., but not limited to, light, visible light, infrared light, etc. The EM radiation emitting device can comprise a light emitting device such as a Light Emitting Diode (LED), Laser Diode, or Superluminescent Diode. The EM radiation absorbing device can comprise a solar cell, for example. The EM radiation is typically emitted by, or absorbed in, an active region of the device.

In one or more embodiments, the controlling can be as follows.

(1) The controlling can be such that the texture or the structures' profile is rough as compared to a wavelength of the light in or outside the group III-nitride semiconductor film.

(2) The controlling can be such that the texture or the structures scatter the light by Rayleigh scattering (e.g., the wavelength of the light is at least 10 times smaller than a size of the texture or the structures), Mie scattering (e.g., wavelength of the light is approximately the same size as the texture or the structures), or geometric scattering (e.g., so that Snell's law of refraction controls, for example, the wavelength can be at least 10 times larger than a size of the texture or the structures).

(3) The controlling can be such that the structures have a tapered profile or cross-section, or have a width at a base of the structures that is larger than a width at a top of the structures.

(4) The controlling can be such that the structures, features, or texture include, but are not limited to, islands, protrusions from a growth plane, facetted structures, pyramids, structures having a triangular or trapezoidal cross-section, conical shapes, structures with sidewalls inclined towards each other to form a peak or taper, or structures having straight or curved sidewalls. A height and/or a base width of the structures can both be 200 nanometers or more, or larger than a wavelength of the light.

(5) The controlling can be such that sidewalls of the structures are inclined at an angle with respect to the horizontal or a planar growth surface in the film (e.g., a planar surface of the light emitting or absorbing active layer of the device, e.g., InGaN quantum well). The angle can be greater than or equal to the critical angle θ_{c} for the light's extraction from (in the case of a light emitting device), or the light's insertion into the film (in the case of a solar cell). The angle can be such that total internal reflection of the light inside the film (or outside) the film is suppressed or minimized.

For example, the sidewalls of the III-nitride semiconductor material can be sloped in order to scatter the guided modes out of the III-nitride semiconductor material rather than reflecting the guided modes back into the III-nitride semiconductor material. Alternatively, the sidewalls can be at a sidewall angle such that light originating from the active region is more likely to be incident on the sidewall at an incident angle smaller than the critical angle for total internal reflection (TIR), so that more of the totally internally reflected guided modes are incident at the top surface within the critical angle for extraction out of the device.

In an example of a solar cell embodiment, the sidewalls can be at a sidewall angle such that light propagating towards the active region is more likely to be incident on the sidewall at an incident angle smaller than the critical angle for total internal reflection (TIR) inside the external medium (the medium external to the active layer), or away from the active layer, so that more light incident from the external medium (e.g., air) at the top surface is within the angle for insertion into the device or the light absorbing active layer. One or more angles of one or more resulting surface(s) (e.g., top surface or sidewalls) of the III-nitride semiconductor material can be controlled.

(7) The controlling can vary the surface coverage of the texturing or the structures. For example, the texturing or structured surface can be such that a density of the structures is at least 50 structures per 25 microns square, or such that the structures or the texture continuously, predominantly, or substantially cover an entire light receiving or light emitting surface of the device. The structures or textured surface can form a periodic pattern (e.g., similar to a photonic crystal) or a non-regular or non-periodic pattern.

(8) The controlling can be such that the light incident on the textured or structured surface deviates from its original path and has a pass path length, through a light absorbing region of the solar cell, that is longer than the path length when the light is incident on a planar surface of a III-nitride semiconductor film in a solar cell.

(9) The controlling can be such that the light is diffracted by the structures. The controlling can be such that the structures or textured surface function as a photonic crystal. However, the controlling can be such that the light is not diffracted. The controlling can be such that the structures or textured surface does not function as a photonic crystal.

(10) The controlling can be such that the size/texture/density/pattern of light scattering features is predetermined, adjusted or controlled to match or obtain a particular to a single pass path length of the light through the device, e.g., solar cell.

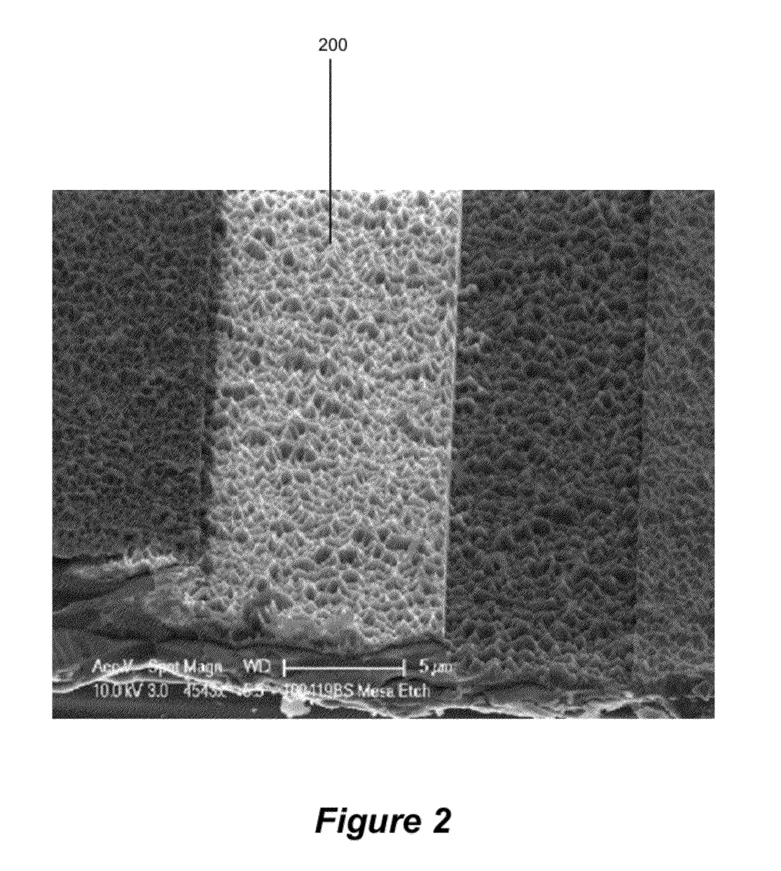

The present invention is intended to cover a device fabricated using these steps, as illustrated in Block 106. FIG. 2 is a Scanning Electron Micrograph of a textured nitride semiconductor film resulting from the above growth procedure (the steps (1)-(9) of Block 102), wherein the textured nitride semiconductor film comprises a top surface with structures 200.

Device Example: Solar Cell

Light trapping is important concept in solar cells, especially for devices with α*L<<1, where α is the absorption coefficient of the material and L is the thickness of the active absorbing region (typically the depletion region thickness, plus the electron and hole diffusion lengths).

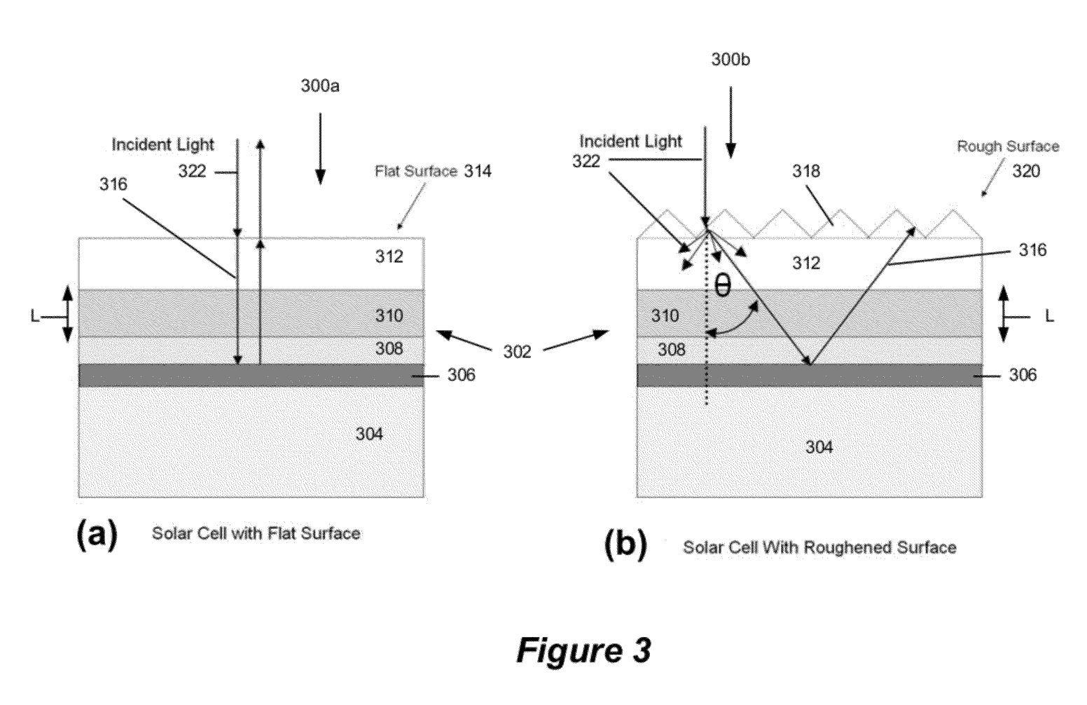

FIGS. 3(a) and 3(b) illustrate a photovoltaic device or solar cell 300a, 300b comprising a III-nitride semiconductor film 302 grown or deposited in the solar cell's device structure. The solar device structure comprises a substrate 304 (e.g., GaN), back contact 306 on or above the substrate, n-type GaN layer 308 on or above the back contact 306, and InGaN/GaN multi quantum wells 310 (the solar cell's light absorbing region) between the n-type GaN layer 308 and a p-type GaN layer 312.

FIG. 3(a) illustrates a solar cell 300a wherein the film 302 has a flat surface 314 and a reflecting back contact 306, wherein the single pass path length (D) of the light 316 through the device is 2*L.

FIG. 3(b), on the other hand, illustrates a solar cell device 300b with a texture or one or more structures 318 grown onto or into a surface of the III-nitride nitride semiconductor film 302 (specifically, the structures 318 are grown onto the surface of p-type GaN layer 312) to form a textured or rough surface 320, wherein the texture or the structures 318 of the structured surface 320 increase absorption of the light 316 in the light absorbing or active region of the solar cell 300b.

By roughening 320 the surface (front, back or both), the incident light 322 is scattered (see FIG. 3(b)), and the single pass path length of the photon through the device 300b is longer than in the flat surface device 300a by a factor of 1/cos θ, where θ is the angle of the scattered photon from vertical. This allows for more of the incident light 322 to be absorbed leading to higher efficiencies. The total path length increase can be found by integrating 2*L/cos θ over all angles.

Advantages and Improvements

The present invention's technique has many advantages over existing texturing techniques currently employed to achieve a textured material. One such technique is the use photo electrochemical (PEC) etching of Nitrogen-face nitride based materials and devices. In order to complete this texturing process, the substrate material must be removed after the device is deposited. Subsequently, PEC etching must then be performed on the N-face of the nitride based device in order to form a textured material.

The current invention distinguishes itself from previous art by allowing for the use of an in-situ technique for texturing of a semiconductor material. This allows for precise control of texturing features, such as shape, height, and density based on process conditions. Benefits also include the elimination of further texturing techniques or steps, thereby reducing overall manufacturing cost and improving product yield.

The present invention can be used to fabricate light emitting devices such as LEDs and laser diodes (LDs), and light absorbing devices such as solar cells.

The realization of a textured III-V material can allow multiple advances in the performance of LED and solar cells devices. Using a textured material, as described in the present invention, for a LED or solar cell device allows for enhanced extraction or collection of light respectively, in comparison to devices without the use of a textured material.

The present invention can also achieve a substantially textured surface for use in electronic devices, e.g., transistors or High Electron Mobility Transistors (HEMTs). There are benefits of using the present invention in electronic devices. Moreover, the present invention's method/process steps can be optimized to meet various device specific requirements.

Possible Modifications

The textured nitride semiconductor thin film can comprise of GaN, AlN, InN, AlGaN, InGaN or AlInN, for example. Moreover, the textured nitride semiconductor thin film can comprise multiple layers having varying or graded compositions. In addition, the textured nitride semiconductor thin film can comprise heterostructures containing layers of dissimilar (Al, Ga, In, B)N composition.

Additionally the textured film can be positioned in any part of the device structure and can be intentionally or unintentionally doped with Magnesium (Mg), Iron (Fe), Silicon (Si), Oxygen (O), Hydrogen (H), Carbon (C), and/or Boron (B).

Additionally, the textured film can be used in a LED device in order to enhance light output characteristics. The textured film can also be used in a solar cell device to enhance light absorption characteristics. However, the textured nitride semiconductor film, comprising a grown textured surface, can be used in a variety of electronic and optoelectronic device structures.

Furthermore, the textured nitride semiconductor film can be located within the semiconductor device or on the top or bottom surfaces of the device. The top or bottom surfaces of the textured nitride semiconductor film can be textured using the process of the present invention, for example.

The textured nitride semiconductor film can also be deposited in any crystallographic nitride direction, such as on a conventional c-plane oriented nitride semiconductor crystal, or on a nonpolar plane such as a-plane or m-plane, or on any semipolar plane. The semi-polar plane, non-polar plane, or c-plane (Ga face or N-face) can be textured, for example.

In one or more embodiments, the textured III-nitride semiconductor film in the light emitting or absorbing device does not contain damage, or contains less damage, as compared to damage formed by etching to create an etched textured or structured surface of a III-nitride semiconductor film in a light emitting or absorbing device, wherein the etched textured or structured surface has a texture, or one or more structures, that increase output power of light from the light emitting device or increase absorption of light in the light absorbing device. The damage can be reduced as compared to wet etching, photoelectrochemical etching, dry etching, or ion-assisted plasma etching of the textured III-nitride semiconductor film, for example.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for fabricating a III-nitride semiconductor film, comprising:
depositing or growing a III-nitride semiconductor film in a semiconductor light absorbing or light emitting device structure; and
growing a textured or structured surface of the III-nitride nitride semiconductor film in situ with the growth or the deposition of the III-nitride semiconductor film, by controlling the growing of the III-nitride semiconductor film to obtain a texture of the textured surface, or one or more structures of the structured surface, that increase output power of light from the light emitting device, or increase absorption of light in the light absorbing device.

2. The method of claim 1, wherein the controlling is such that the texture or the structures' profile is rough as compared to a wavelength of the light in the group III-nitride semiconductor film.

3. The method of claim 1, wherein the controlling is such that the texture or the structures scatter the light by Rayleigh scattering, Mie scattering, or geometric scattering.

4. The method of claim 1, wherein the controlling is such that the structures have a width at a base of the structures that is larger than a width at a top of the structures.

5. The method of claim 1, wherein the controlling is such that the structures have a height and a base width of 200 nanometers or more, or larger than a wavelength of the light.

6. The method of claim 1, wherein the controlling is such that sidewalls of the structures are inclined at an angle greater than a critical angle for the light's extraction from, or the light's insertion into the film, or such that total internal reflection of the light inside the film or outside the film is suppressed or minimized.

7. The method of claim 1, wherein the controlling is such that a density of the structures is at least 50 structures per 25 microns square, or at least as dense and as rough as illustrated in FIG. 2.

8. The method of claim 1, wherein the controlling is such that the structures or the texture predominantly or substantially cover an entire light receiving or light emitting surface of the device.

9. The method of claim 1, wherein the controlling is such that the light incident on the textured or structured surface deviates from its original path and has a pass path length, through a light absorbing region of the light absorbing that is a solar cell, that is longer than a path length when the light is incident on a planar or flat surface of a III-nitride semiconductor film used in a solar cell.

10. The method of claim 1, wherein the III-nitride semiconductor film is deposited in a light emitting diode device.

11. The method of claim 1, wherein the III-nitride semiconductor film is deposited in a solar cell device.

12. The method of claim 1, wherein the III-nitride semiconductor film is deposited on a surface the semiconductor device.

13. The method of claim 1, wherein the III-nitride semiconductor film is deposited on a bottom of the semiconductor device.

14. The method of claim 1, wherein the III-nitride semiconductor film is deposited within the semiconductor device.

15. The method of claim 1, wherein the III-nitride semiconductor film is deposited and doped with Mg, Fe, C, O, Si, B or H.

16. The method of claim 1, wherein the III-nitride semiconductor film comprises one or more layers of intentionally doped or unintentionally doped materials.

17. The method of claim 1, wherein the III-nitride semiconductor film comprises multiple layers having varying or graded compositions.

18. The method of claim 1, wherein the III-nitride semiconductor film comprises a heterostructure comprising layers of dissimilar (Al, Ga, In, B)N composition.

19. The method of claim 1, wherein the III-nitride semiconductor film comprises GaN, AlN, InN, AlGaN, InGaN or AlInN.

20. The method of claim 1, wherein the III-nitride semiconductor film is a film grown in any crystallographic nitride direction, including a conventional c-plane, a nonpolar a-plane or m-plane, or any semipolar plane oriented nitride semiconductor crystal.

21. A light emitting or light absorbing device, comprising
a III-nitride semiconductor film grown or deposited in a semiconductor light absorbing or light emitting device structure; and
a texture or one or more structures grown onto a surface of the III-nitride nitride semiconductor film to form a textured or structured surface, wherein the texture or the structures of the structured surface increase an output power of light from the light emitting device, or increase absorption of light in the light absorbing device.

22. The device of claim 21, wherein the texture or the structures' profile is rough as compared to a wavelength of the light in the group III-nitride semiconductor film.

23. The device of claim 21, wherein the texture or the structures scatter the light by Rayleigh scattering, Mie scattering, or geometric scattering.

24. The device of claim 21, wherein the structures have a width at a base of the structures that is larger than a width at a top of the structures.

25. The device of claim 21, wherein the structures have a height and a base width of 200 nanometers or more, or larger than a wavelength of the light.

26. The device of claim 21, wherein sidewalls of the structures are inclined at an angle greater than a critical angle for the light's extraction from, or the light's insertion into the film, or such that total internal reflection of the light inside the film or outside the film is suppressed or minimized.

27. The device of claim 21, wherein a density of the structures is at least 50 structures per 25 micrometers square, or at least as dense and as rough as illustrated in FIG. 2.

28. The device of claim 21, wherein the structures or the texture predominantly or substantially cover an entire light receiving or light emitting surface of the device.

29. The device of claim 21, wherein the light incident on the textured or structured surface deviates from its original path and has a pass path length, through a light absorbing region of the light absorbing that is a solar cell, that is longer than a path length when the light is incident on a planar surface of a III-nitride semiconductor film used in a solar cell.

30. The device of claim 21, wherein the III-nitride semiconductor film is deposited in a light emitting diode device.

31. The device of claim 21, wherein the III-nitride semiconductor film is deposited in a solar cell device.

32. The device of claim 21, wherein the III-nitride semiconductor film is deposited on a surface the semiconductor device.

33. The device of claim 21, wherein the III-nitride semiconductor film is deposited on a bottom of the semiconductor device.

34. The device of claim 21, wherein the III-nitride semiconductor film is deposited within the semiconductor device.

35. The device of claim 21, wherein the III-nitride semiconductor film is deposited and doped with Mg, Fe, C, O, Si, B or H.

36. The device of claim 21, wherein the III-nitride semiconductor film comprises one or more layers of intentionally doped or unintentionally doped materials.

37. The device of claim 21, wherein the III-nitride semiconductor film comprises multiple layers having varying or graded compositions.

38. The device of claim 21, wherein the III-nitride semiconductor film comprises a heterostructure comprising layers of dissimilar (Al, Ga, In, B)N composition.

39. The device of claim 21, wherein the III-nitride semiconductor film comprises GaN, AlN, InN, AlGaN, InGaN or AlInN.

40. The device of claim 21, wherein the III-nitride semiconductor film is a film grown in any crystallographic nitride direction, including a conventional c-plane, a nonpolar a-plane or m-plane, or any semipolar plane oriented nitride semiconductor crystal.

41. The device of claim 21, wherein the III-nitride semiconductor film having the textured surface does not contain damage, or contains less damage, as compared to damage formed by etching to create an etched textured or structured surface of a III-nitride semiconductor film in a light absorbing or light emitting device, wherein the etched textured or structured surface has a texture, or one or more structures, that increase output power of light from the light emitting device or increase absorption of light in the light absorbing device.
